(19) United States
(12) Patent Application Publication
(10) Pub. No.: US 2012/0168304 A1
(43) Pub. Date: Jul. 5, 2012

(54) Physical Vapor Deposition Tool with Gas Separation

(76) Inventors: Hien Minh Huu Le, San Jose, CA (US); Mohd Fadzli Anwar Hassan, San Francisco, CA (US)

(21) Appl. No.: 12/982,397

(22) Filed: Dec. 30, 2010

(51) Int. Cl. C23C 14/34

(52) U.S. Cl. 204/298.07

(57) ABSTRACT

Embodiments of the current invention describe a physical vapor deposition tool. The physical vapor deposition tool includes a housing, a substrate support positioned within the housing and configured to support a substrate, a first process head positioned over the substrate support and having a first target, a second process head positioned over the substrate support and having a second target, and a gas line to provide gas to the first process head. The first process head and the gas line are configured such that the gas provided to the first process head through the gas line interacts with ions ejected from the first target and does not interact with ions ejected from the second target.

### FIELD OF THE INVENTION

The present invention relates to apparatus and method for layer deposition on a substrate. More particularly, this invention relates to a physical vapor deposition apparatus having gas separation provided for the process heads.

### BACKGROUND OF THE INVENTION

Deposition processes are commonly used in semiconductor manufacturing to deposit a layer of material onto a substrate. Processing is also used to remove layers, defining features (e.g., etch), preparing layers (e.g., cleans), doping or other processes that do not require the formation of a layer on the substrate. Processes and process shall be used throughout the application to refer to these and other possible known processes used for semiconductor manufacturing and any references to a specific process should be read in the context of these other possible processes. In addition, similar processing techniques apply to the manufacture of integrated circuits (IC) semiconductor devices, flat panel displays, optoelectronics devices, data storage devices, magneto electronic devices, magneto optic devices, packaged devices, and the like.

One common method for forming layers on substrates is physical vapor deposition (PVD). PVD generally involves ejecting material from a “target” of the material to be deposited onto the substrate. One of the steps typically included is to expose the target to a carrier gas, such as argon or krypton. However, in order to form more complex layers, such as oxides and nitrides, an additional “reactive” gas (e.g., oxygen or nitrogen) is often also introduced.

In existing PVD tools that utilize more than one target, simultaneously depositing, for example, a pure material, such as a metal, and an oxide or nitride is difficult at best because the reactive gas from one target tends to interact with ions ejected from another target. As a result, the layer deposited on the substrate may be a mixture of, for example, two oxides or two nitrides, as opposed to a mixture of a pure material and the oxide/nitride.

### BRIEF DESCRIPTION OF THE DRAWINGS

Various embodiments of the invention are disclosed in the following detailed description and the accompanying drawings:

FIG. 1 is a simplified cross-sectional diagram illustrating a physical vapor deposition (PVD) tool according to one embodiment of the present invention;

FIG. 2 is an isometric view of an exterior of the PVD tool of FIG. 1; and

FIG. 3 is a cross-sectional schematic of a portion of the PVD tool of FIG. 1 and a processing fluid system.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The embodiments described below provide details for a multi-region processing system and associated processing heads that enable processing a substrate in a combinatorial fashion. Thus, different regions of the substrate may have different properties, which may be due to variations of the materials, unit processes (e.g., processing conditions or parameters) and process sequences, etc. Within each region the conditions are preferably substantially uniform so as to mimic conventional full wafer processing within each region, however, valid results can be obtained for certain experiments without this requirement. In one embodiment, the different regions are isolated so that there is no inter-diffusion between the different regions.

In addition, the combinatorial processing of the substrate may be combined with conventional processing techniques where substantially the entire substrate is uniformly processed (e.g., subjected to the same materials, unit processes and process sequences). Thus, the embodiments described herein can pull a substrate from a manufacturing process flow, perform combinatorial deposition processing and return the substrate to the manufacturing process flow for further processing. Alternatively, the substrate can be processed in an integrated tool that allows both combinatorial and conventional processing in a single chamber or various chambers attached around a central chamber. Consequently, in one substrate, information concerning the varied processes and the interaction of the varied processes with conventional processes can be evaluated. Accordingly, a multitude of data is available from a single substrate for a desired process.

The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a semiconductor device. A global optimum sequence order is therefore derived and as part of this derivation, the unit processes, unit process parameters and materials used in the unit process operations of the optimum sequence order are also considered.

The embodiments described further below analyze a portion or sub-set of the overall process sequence used to manufacture a semiconductor device. Once the subset of the process sequence is identified for analysis, combinatorial process sequence integration testing is performed to optimize the materials, unit processes and process sequence used to build that portion of the device or structure. During the processing of some embodiments described herein, structures are formed on the processed semiconductor substrate, which are equivalent to the structures formed during actual production of the semiconductor device. For example, such structures may include, but would not be limited to, trenches, vias, interconnect lines, capping layers, masking layers, diodes, memory elements, gate stacks, transistors, or any other series of layers or unit processes that create an intermediate structure found on semiconductor chips. While the combinatorial processing varies certain materials, unit processes, or process sequences, the composition or thickness of the layers or structures or the action of the unit process, such as cleaning, surface preparation, etch, deposition, planarization, implantation, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, or process sequences) and not the lack of process uniformity.

According to a particular aspect of the invention described herein, a physical vapor deposition tool is provided with a cluster of process heads (or deposition guns) suspended above a substrate to be processed. At least one gas line is provided to deliver a processing gas to a target of one of the process heads. The process head and/or the gas line is configured such that gas delivered to the target only interacts with ions ejected from that particular target and not ions ejected from the other targets.

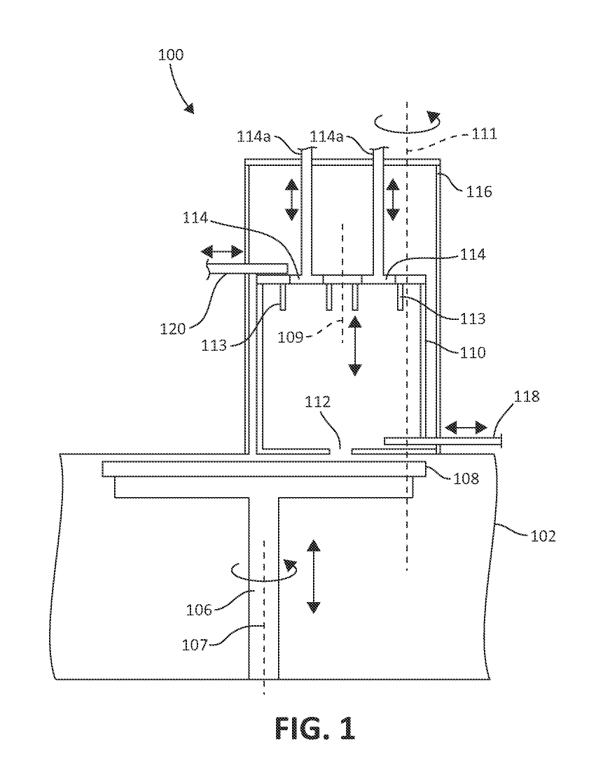

FIG. 1 provides a simplified illustration of a physical vapor deposition (PVD) tool (and/or processing chamber and/or system) configured to combinatorially process a substrate disposed therein, in accordance with one embodiment of the invention. The PVD tool 100 includes a bottom chamber portion 102 disposed under a top chamber portion 116. Within the bottom chamber portion 102, a substrate support 106 is configured to hold a substrate 108 and may be any known substrate support, including but not limited to a vacuum chuck, electrostatic chuck, or other known mechanisms. The substrate support 106 is capable of rotating around a central axis 107 thereof that is perpendicular to the surface of the substrate 108. In addition, the substrate support 106 may move in a vertical direction or in a planar direction. It should be appreciated that the rotation and movement in the vertical direction or planar direction may be achieved through known drive mechanisms which include magnetic drives, linear drives, worm screws, lead screws, a differentially pumped rotary feed through drive, etc.

The substrate 108 may be a conventional, round substrate (or wafer) having a diameter of, for example, 200 millimeter (mm) or 300 mm. In other embodiments, the substrate 108 may have other shapes, such as a square or rectangular. It should be understood that the substrate 108 may be a blanket substrate (i.e., having a substantial uniform surface), a coupon (e.g., partial wafer), or even a patterned substrate having predefined regions. In another embodiment, the substrate 108 may have regions defined through the processing described herein.

The term region is used herein to refer to a localized area on a substrate which is, was, or is intended to be used for processing or formation of a selected material. The region may include one region and/or a series of regular or periodic regions pre-formed on the substrate. The region may have any convenient shape, e.g., circular, rectangular, elliptical, wedge-shaped, etc. In the semiconductor field a region may be, for example, a test structure, single die, multiple die, portion of a die, other defined portion of substrate, or a undefined area of a, e.g., blanket substrate which is defined through the processing.

The top chamber portion 116 of the PVD tool 100 includes a process kit shield 110, which defines a confinement region over a radial portion of substrate 108. The process kit shield 110 essentially a sleeve having a base (optionally integral with the shield) and an optional top within chamber 100 that may be used to confine a plasma generated therein used for physical vapor deposition (PVD) or other flux based processing. The generated plasma will dislodge particles from a target to process (e.g., be deposited) on an exposed surface of the substrate 108 to combinatorially process regions of the substrate in one embodiment.

The process kit shield 110 is capable of being moved in and out of chamber 100. That is, the process kit shield 110 is a replaceable insert. The process kit shield 110 includes an optional top portion, sidewalls, and a base. In one embodiment, the process kit shield 110 is configured in a cylindrical shape. However, other shapes may be used.

The base (or base plate) of process kit shield 110 includes an aperture 112 through which a portion of a surface of the substrate 108 is exposed for deposition or some other suitable semiconductor processing operation. Within the top portion 116, a cover plate 118 is moveably disposed over the base of process kit shield 110. In one embodiment, the cover plate 118 may slide across a bottom surface of the base of process kit shield 110 in order to cover or expose the aperture 112. In another embodiment, the cover plate 118 is controlled through an arm extension which moves the cover plate to expose or cover aperture 112 as will be described in more detail below. It should be noted that although a single aperture 112 is illustrated, multiple apertures may be included. In such an embodiment, each aperture may be associated with a dedicated cover plate or a cover plate may be configured to cover more than one aperture simultaneously or separately. Alternatively, the aperture 112 may be a larger opening and the plate 118 may extend with that opening to either completely cover it or place one or more fixed apertures within that opening for processing the defined regions.

The optional top plate of sleeve 110 of FIG. 1 may function as a datum shield. Process heads 114 (also referred to as deposition guns) are disposed within slots defined within the datum shield in accordance with one embodiment of the invention. In the depicted embodiment, a datum shield slide cover plate 120 is included and functions to seal off one or more of the process heads 114 (or deposition guns) when not in use.

Although only two process heads 114 are shown in FIG. 1, it should be understood that the PVD tool 100 may include more, such as three, four, or more process heads, each of which includes a target, as described below. The multiple process heads may be referred to as a cluster of process heads 114. The process heads 114 are moveable in a vertical direction so that one or both may be lifted from the slots of the datum shield (i.e., the top portion of sleeve 110). In addition, the cluster of process heads 114 may be rotatable around an axis 109.

When the process heads 114 are lifted, the slide cover plate 120 may be transitioned to isolate the lifted process heads from the processing area defined within the process kit shield 110. As such, the process heads 114 may be selectively isolated from certain processes. It should be noted that although only one slide cover plate 120 is shown, multiple slide cover plates may be included so that each slot or opening of the datum shield is associated with a cover plate. Alternatively, the slide cover plate 120 may be integrated with the top portion of the shield unit 110 to cover the opening as the process head is lifted or individual covers can be used for each target.

The cluster of process heads 114 enables co-sputtering of different materials onto the substrate 108, as well as a single material being deposited and various other processes. Accordingly, numerous combinations of target materials, multiple deposition guns having the same material, or any combination thereof may be applied to the different regions of the substrate so that an array of differently processed regions results.

Still referring to FIG. 1, the PVD tool 100 also includes an individual process head shields 113 for each of the process heads 114. As shown, each process head shield 113 extends downwards from the top portion of the process kit shield 110 around one of the slots into which the process heads 114 are inserted. Further details of the individual process head shield 113 are provided below.

The top section 116 of the PVD tool 100 includes sidewalls and a top plate which house process kit shield 110. Arm extensions 114a, each of which is attached to one of the process heads 114, extend through an upper end of the top portion 116. The arm extensions 114a may be attached to a suitable drive (or actuator), such as lead screws, worm gears, etc., which are configured to vertically move the process heads 114 relative to the top portion 116. The arm extensions 114a may be pivotably affixed to the process heads 114 to enable the process heads to tilt relative to a vertical axis (e.g., axis 107). In one embodiment, the process heads 114 tilt toward the aperture 112. In another embodiment, the arm extensions 114a are attached to a bellows that allow for the vertical movement and tilting of the process heads 114. Where a datum shield is utilized, the openings are configured to accommodate the tilting of the process heads 114. In one embodiment, the process heads 114 are tilted by ten degrees or less relative to the vertical axis. It should be appreciated that the tilting of the process heads 114 enables tuning so that the deposition guns may be tilted toward the aperture 112 to further enhance uniformity of a layer of material deposited on the substrate 108 through the aperture 112.

As indicated in FIG. 1, the process kit shield 110 is moveable in a vertical direction and is configured to rotate around an axis 111. It should be appreciated that the axis 111 around which process kit shield 110 rotates is offset from both the axis 107 about which the substrate support 106 rotates and the axis 109 of the cluster of process heads 114. As such, a plurality of regions on the substrate 108 may be exposed for combinatorial processing, by rotating the substrate 108, the cluster of process heads 114, and the process kit shield 110 between various angular positions. That is, a first deposition process may be performed on a first portion of the substrate 108, and a second deposition process may be performed on a second portion of the substrate 108.

As the process kit shield 110 rotates, the relative position of the process heads 114 and the aperture 112 is constant, thus the uniformity of the processing of the region on the substrate 108 from site to site is improved, as no variability due to process head angle or relative positioning is experienced. While the process heads 114 are shown as centered on the aperture 112, additional process heads may be offset from the cluster of process heads 114 for doping, implantation, or deposition of small amounts of a material, e.g., 1-10% without limitation.

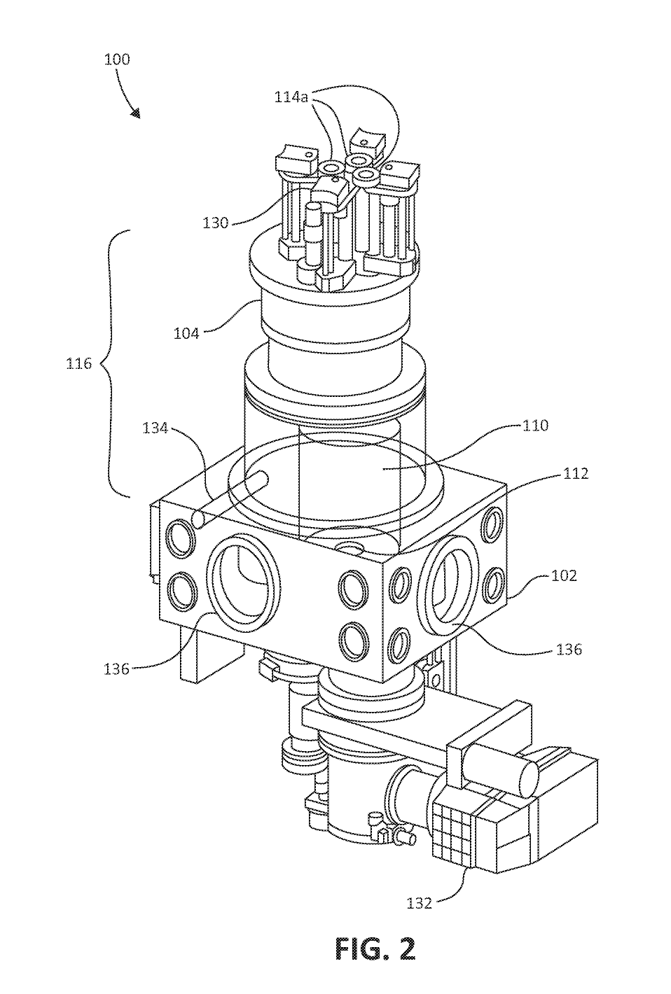

FIG. 2 illustrates an exterior of the PVD tool 100, according to one embodiment of the invention. As shown, the bottom chamber portion 102 includes access ports 136 which may be utilized for access to the chamber for pulling a vacuum, or other process monitoring operations. The bottom chamber portion 102 also includes a slot valve 134 which enables access for a substrate into and out of the bottom chamber portion 102. In one embodiment, the PVD tool 100 may be part of a cluster tool having multiple processing tools in which a robot may be utilized to move substrates into and out of the PVD tool 100 through the slot valve 134, as well as to and from the other processing tools.

In the depicted embodiment, the top chamber portion 116 includes a rotary stage 104 which is utilized to rotate the process kit shield 110 with the process heads 114 (FIG. 1). The arm extensions 114a protrude through a top surface of the rotary stage 104. It should be noted that four arm extensions 114a are shown in FIG. 2, as the PCD tool 100 may include four (or more) process heads 114, as alluded to above. Also protruding through a top surface of the rotary stage 104 is a heat lamp 130 which is disposed within the top chamber portion 116 in order to supply heat for processing within the chamber.

The PVD tool 100 also includes a drive 132 below the bottom chamber portion 102, which may be used to provide the rotational means for rotating the substrate support 106 (FIG. 1). Additionally, the drive 132 may provide the mechanical means for raising or lowering the substrate support 106. As described above, the process heads 114 rotate within the top chamber portion 116 about an axis (i.e., axis 109 in FIG. 1) different than the axis (i.e., axis 107 in FIG. 1) about which the substrate support 106 rotates.

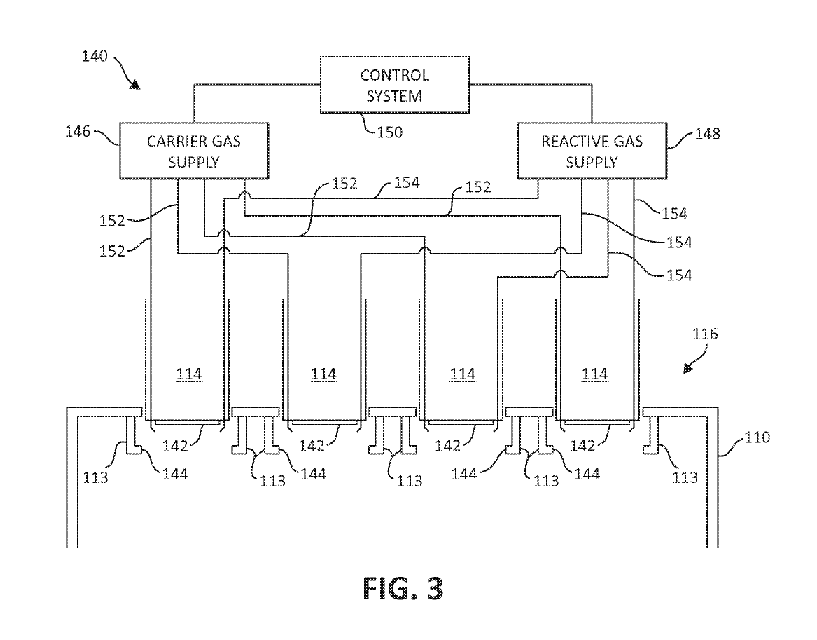

FIG. 3 schematically illustrates a section of the top chamber portion 116 of the PVD tool 100, along with a processing fluid system 140, in accordance with one embodiment of the present invention. A cluster of four process heads 114 is shown, for clarity, arranged in a linear manner. However, as described above, the process heads 114 may be arranged about an axis (i.e., axis 109 in FIG. 1), as indicated by the arrangement of the arm extensions 114 a shown in FIG. 2. It should be noted that although all four process heads 114 are shown as being inserted into the slots in the top portion of the process kit shield 110, one or more of them may be lifted and isolated (i.e., by the slide cover plate 120 in FIG. 1) during processing. The process heads 114 may be in relatively close proximity to each other. In one embodiment, the process heads 114 are arranged such that a distance between adjacent process heads 114 is between 1 and 4 centimeters (cm).

As described above, each of the process heads 114 includes a target 142 made of the material (or materials) to be deposited on the substrate 108 (FIG. 1). In one embodiment, the four targets 142 are made of aluminum, silicon, molybdenum, and titanium, respectively (or a combination thereof). Although not specifically shown, the targets 142 are connected to a power supply, as is the substrate support 106 (FIG. 1).

As shown, each of the process heads 114 and/or the targets 142 is provided with one of the individual process head shields 113 extending downwards from the top portion of the process kit shield 110. More particularly, each of the process head shields 113 is arranged about a respective one of the slots in the process kit shield 110 into which the process heads 114 are inserted. Similar to the process kit shield 110, the process head shields 113 are, in one embodiment, cylindrical in shape. However, other configurations could be used, such as slits between adjacent process heads 114. Each of the process head shields 113 includes a lip 144 that extends inwards towards a region below the respective target 142.

The processing fluid system 140 includes a carrier gas supply (or supplies) 146, a reactive gas supply (or supplies) 148, and a control system 150. The carrier gas supply 146 includes one or more supplies of suitable carrier gases for PVD processing, such as argon, krypton, or a combination thereof. The reactive gas supply 148 includes one of more supplies of suitable reactive gases for forming various oxides and nitrides with PVD processing, such as oxygen, nitrogen, or a combination thereof. The control system 150 includes, for example, a processor and memory (i.e., a computing system) in operable communication with the carrier gas supply 146 and the reactive gas supply 148 and configured to control the flow of carrier and reactive gases to the process heads 114 as described below.

Still referring to FIG. 3, separate carrier gas lines (or conduits) 152 are provided for delivering a carrier gas from the carrier gas supply 146 to each of the targets 142 individually. However, during processing, the same carrier gas (e.g., argon) may be delivered to all of the targets 142. Similarly, separate reactive gas lines 154 are provided for selectively delivering a reactive gas from the reactive gas supply 148 to each of the targets 142 individually.

According to one aspect of the present invention, the arrangement of the gas lines, particularly the reactive gas lines 154, along with the use of the process head shields 113, allows for processing gases delivered to one of the targets 142 to only interact with ions ejected from that particular target 142. That is, the reactive gas lines 154 and the process head shields 113 are configured such that reactive gas provided to one of the process heads 114 and/or target 142 does not interact with the ions ejected from another one of the targets 142.

This may result from the reactive gas being delivered to a particular location relative to the respective target 142 (i.e., a region just below the target 142), as well as a “trapping” effect caused by the process head shields 113 (i.e., the process head shields 113 sufficiently prevent diffusion of the reactive gas such that substantially all of the reactive gas interacts with ions ejected from the respective target). As such, the process head shields 113 may extend enough below the targets 142 such that the gases are contained within the process head shields 113. The lips 144 may enhance the containment of the gases. The size of the process head shields 113 and the lips 144 may be altered to optimize the gas separation effect.

However, it should be noted that the flow rate of the reactive gases may also be adjusted to optimize this effect. For example, depending on the size of the process head shields 113, the maximum amount of reactive gas may be delivered to the targets 142, which does not cause excessive gas from one process head 114 to bleed to another process head 114. Also, the timing of the release of gas may be used. For example, just enough reactive gas may be provided to cause the desired reaction, and then the flow of gas may be stopped. It should also be noted that a similar effect may be obtained for the carrier gases, if so desired.

As a result, the range of materials that may be simultaneously deposited on the portion of the substrate 108 exposed through the aperture 112 (FIG. 1) is increased. For example, a pure metal, such as aluminum, may be deposited by process head 114 while an oxide, such as silicon oxide, is deposited from another process head 114. As another example, a nitride, such as titanium nitride, may be deposited by one process head 114 while an oxide is deposited by another process head 114. As a further example, a silicon oxynitride may be deposited by using a silicon target and oxygen and nitrogen reactive gas in one process head and a pure metal, such as silver, in another process head.

The PVD tool (or system) 100 described with respect to FIGS. 1-3 may be incorporated into a cluster-tool in which conventional processing tools are included. Thus, the substrate 108 may be conventionally processed (i.e., the whole wafer subject to one process or set of processes to provide uniform processing across the wafer) and placed into the PVD tool 100 in order to evaluate different processing techniques on a single substrate. Furthermore, the embodiments described herein provide for a “long throw” chamber in which a distance from a top surface of a substrate being processed and the surface of a target on the deposition guns is greater than four diameters of the targets. For example, a target may have a size of two to three inches which would make the distance from a top surface of the substrate being processed and the target between about 8 inches (i.e., 200 mm) and about 12 inches (i.e., 300 mm). In another embodiment, the distance to the targets is greater than six diameters of the targets. This distance will enhance the uniformity of the material being deposited within the region defined by aperture 112 over the substrate. That is, while the substrate may have differently processed regions, each region will be substantially locally uniform in order to evaluate the variations enabled through the combinatorial processing. It should be noted that the depositions rate will decrease with the increase in target to substrate distance. This increase in distance would negatively impact throughput for a production tool and therefore is not considered for conventional processing tool. However, the resulting uniformity and multitude of data obtained from processing the single substrate combinatorially far outweighs any throughput impact due to the decrease in the deposition rate. It is noted, that the chamber does not require long throw to be effective, but such an arrangement is a configuration that may be implemented. In the embodiments described above, process kit shield 110 is optional. For example, with regard to a single head utilized in a conventional sputtering chamber, the process kit can be eliminated.

In one embodiment, a physical vapor deposition tool is provided. The physical vapor deposition tool includes a housing, a substrate support positioned within the housing and configured to support a substrate, a first process head positioned over the substrate support and having a first target, a second process head positioned over the substrate support and having a second target, and a gas line to provide gas to the first process head. The first process head and the gas line are configured such that the gas provided to the first process head through the gas line interacts with ions ejected from the first target and does not interact with ions ejected from the second target.

In another embodiment, a physical vapor deposition tool is provided. The physical vapor deposition tool includes a housing, a rotatable substrate support positioned within the housing and configured to support a substrate, a first process head positioned over the substrate support and having a first target, a second process head positioned over the substrate support and having a second target, a base plate positioned between the substrate support and the first and second process heads, the base plate having an opening therethrough for exposing a portion of the substrate to at least one of the first process head and the second process head, at least one carrier gas line to provide carrier gas to the first process head and the second process head, and a reactive gas line to provide reactive gas to the first process head. The first process head and the reactive gas line are configured such that the reactive gas provided to the first process head through the reactive gas line interacts with ions ejected from the first target and does not interact with ions ejected from the second target.

In a further embodiment, a physical vapor deposition tool system is provided. The physical vapor deposition tool system includes a housing, a substrate support positioned within the housing and configured to support a substrate, the substrate support being rotatable about an axis, a first process head positioned over the substrate support and having a first target, a second process head positioned over the substrate support and having a second target, a base plate positioned between the substrate support and the first process head and the second process head, the base plate having an opening therethrough such that when the substrate support is rotated to a first angular position about the axis, a first portion of the substrate is exposed to at least one of the first process and the second process head through the opening, and when the substrate support is rotated to a second angular position about the axis, a second portion of the substrate is exposed to at least one of the first process and the second process head through the opening, a carrier gas supply comprising a carrier gas, at least one carrier gas line in fluid communication with the carrier gas supply and configured to provide the carrier gas to the first process head and the second process head, a reactive gas supply comprising a reactive gas, and a reactive gas line in fluid communication with the reactive gas supply and configured to provide the reactive gas to the first process head. The first process head and the reactive gas line are configured such that the reactive gas provided to the first process head through the reactive gas line interacts with ions ejected from the first target and does not interact with ions ejected from the second target.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A physical vapor deposition tool comprising:
a housing;
a substrate support positioned within the housing and configured to support a substrate;
a first process head positioned over the substrate support and having a first target;
a second process head positioned over the substrate support and having a second target; and
a gas line to provide gas to the first process head,
wherein the first process head and the gas line are configured such that the gas provided to the first process head through the gas line interacts with ions ejected from the first target and does not interact with ions ejected from the second target.

2. The physical vapor deposition tool of claim 1, further comprising a base plate positioned above the substrate support and below the first process head and the second process head, the base plate having an opening therethrough for exposing a portion of the substrate to at least one of the first process head and the second process head.

3. The physical vapor deposition tool of claim 2, wherein the substrate support is rotatable about an axis, wherein the axis extends in a direction that is substantially perpendicular to a surface of the substrate and is offset from the opening through the base plate.

4. The physical vapor deposition tool of claim 3, further comprising a moveable plate positioned above the base plate, the moveable plate having an aperture for exposing a portion of the opening through the base plate to at least one of the first process head and the second process head.

5. The physical vapor deposition tool of claim 4, wherein when the substrate support is rotated to a first angular position about the axis, a first portion of the substrate is exposed to at least one of the first process and the second process head through the opening through the base plate and the aperture in the moveable plate, and when the substrate support is rotated to a second angular position about the axis, a second portion of the substrate is exposed to at least one of the first process and the second process head through the opening through the base plate and the aperture in the moveable plate, and wherein the first process head and the second process head are configured to perform a first vapor deposition process on the first portion of the substrate and a second vapor deposition process on the second portion of the substrate.

6. The physical vapor deposition tool of claim 5, further comprising a second gas line to provide gas to the second process head, wherein the second process head and the second gas line are configured such that the second gas provided to the second process head through the second gas line interacts with ions ejected from the second target and does not interact with ions ejected from the first target.

7. The physical vapor deposition tool of claim 6, wherein the gas line is a first reactive gas line and the second gas line is a second reactive gas line, and further comprising at least one carrier gas line to carrier gas to provide carrier gas to the first process head and the second process head.

8. The physical vapor deposition tool of claim 7, wherein the first reactive gas line is in fluid communication with a supply of a first reactive gas and the second reactive gas line is in fluid communication with a supply of a second reactive gas, wherein each of the first reactive gas and the second reactive gas comprises oxygen, nitrogen, or a combination thereof.

9. The physical vapor deposition tool of claim 8, wherein the at least one carrier gas line is in fluid communication with a supply of a carrier gas, wherein the carrier gas comprises argon, krypton, or a combination thereof.

10. The physical vapor deposition tool of claim 9, wherein each of the first target and the second target comprises aluminum, silicon, molybdenum, titanium, or a combination thereof.

11. A physical vapor deposition tool comprising:
a housing;
a rotatable substrate support positioned within the housing and configured to support a substrate;
a first process head positioned over the substrate support and having a first target;
a second process head positioned over the substrate support and having a second target;
a base plate positioned between the substrate support and the first and second process heads, the base plate having an opening therethrough for exposing a portion of the substrate to at least one of the first process head and the second process head;
at least one carrier gas line to provide carrier gas to the first process head and the second process head; and
a reactive gas line to provide reactive gas to the first process head,
wherein the first process head and the reactive gas line are configured such that the reactive gas provided to the first process head through the reactive gas line interacts with ions ejected from the first target and does not interact with ions ejected from the second target.

12. The physical vapor deposition tool of claim 11, wherein the at least one carrier gas line is in fluid communication with a supply of a carrier gas, wherein the carrier gas comprises argon, krypton, or a combination thereof.

13. The physical vapor deposition tool of claim 12, wherein the reactive gas line is in fluid communication with a supply of reactive gas, wherein the reactive gas comprises oxygen, nitrogen, or a combination thereof.

14. The physical vapor deposition tool of claim 11, further comprising a second reactive gas line to provide reactive gas to the second process head, wherein the second process head and the second reactive gas line are configured such that the reactive gas provided to the second process head through the second reactive gas line interacts with ions ejected from the second target and does not interact with ions ejected from the first target.

15. The physical vapor deposition tool of claim 11, further comprising a target shield coupled to the housing and extending downwards around a periphery of the first target, the target shield being configured to at least partially block the reactive gas provided to the first process head from interacting with ions ejected from the second target.

16. A physical vapor deposition tool system comprising:
a housing;
a substrate support positioned within the housing and configured to support a substrate, the substrate support being rotatable about an axis;
a first process head positioned over the substrate support and having a first target;
a second process head positioned over the substrate support and having a second target;
a base plate positioned between the substrate support and the first process head and the second process head, the base plate having an opening therethrough such that when the substrate support is rotated to a first angular position about the axis, a first portion of the substrate is exposed to at least one of the first process and the second process head through the opening, and when the substrate support is rotated to a second angular position about the axis, a second portion of the substrate is exposed to at least one of the first process and the second process head through the opening;
a carrier gas supply comprising a carrier gas;
at least one carrier gas line in fluid communication with the carrier gas supply and configured to provide the carrier gas to the first process head and the second process head;
a reactive gas supply comprising a reactive gas; and
a reactive gas line in fluid communication with the reactive gas supply and configured to provide the reactive gas to the first process head,
wherein the first process head and the reactive gas line are configured such that the reactive gas provided to the first process head through the reactive gas line interacts with ions ejected from the first target and does not interact with ions ejected from the second target.

17. The physical vapor deposition tool system of claim 16, further comprising a control subsystem configured to cause the ions to be ejected from the first target and the second target such that a first vapor deposition process is performed on the first portion of the substrate and a second vapor deposition process is performed on the second portion of the substrate.

18. The physical vapor deposition tool system of claim 17, wherein the carrier gas comprises argon, krypton, or a combination thereof.

19. The physical vapor deposition tool system of claim 18, further comprising:
a second reactive gas supply comprising a second reactive gas; and
a second reactive gas line in fluid communication with the second reactive gas supply and configured to provide the second reactive gas to the second process head,
wherein the second process head and the second reactive gas line are configured such that the second reactive gas provided to the second process head through the second reactive gas line interacts with ions ejected from the second target and does not interact with ions ejected from the first target.

20. The physical vapor deposition tool system of claim 20, wherein each of the reactive gas and the second reactive gas comprises oxygen, nitrogen, or a combination thereof.
